(19) United States
(12) Patent Application Publication
(10) Pub. No.: US 2012/0104977 A1
(43) Pub. Date: May 3, 2012

(54) HIGH PERFORMANCE LED GROW LIGHT

(75) Inventors: Cammie McKenzie, Santa Clara, CA (US); Julie E. McKenzie, Santa Clara, CA (US)

(73) Assignee: HGL TECHNOLOGIES LLC, Reno, NV (US)

(21) Appl. No.: 13/347,971

(22) Filed: Jan. 11, 2012

Related U.S. Application Data
(63) Continuation-in-part of application No. 13/189,009, filed on Jul. 22, 2011.
(60) Provisional application No. 61/366,861, filed on Jul. 22, 2010.

(51) Int. Cl. H05B 37/02; H01L 27/15

(52) U.S. Cl. 315/312; 257/88; 257/E27.121

(57) ABSTRACT

High performance LED lights and methods of manufacturing high performance LED lights are disclosed. Features of a light may include, inter alia, LED elements with acute angle lenses, and LED distributions that optimize light intensity over a desired area. In grow light applications, a light may incorporate LED wavelengths that maximize photosynthesis, plant growth and flowering. The light may also optionally provide for visibility of plant growth and the work area.

### CROSS-REFERENCE TO RELATED APPLICATIONS

This application is a continuation-in-part of U.S. patent application Ser. No. 13/189,009, entitled “HIGH PERFORMANCE LED GROW LIGHT”, filed on Jul. 22, 2011, which claims priority of U.S. Provisional Application 61/366,861, entitled “HIGH PERFORMANCE LED GROW LIGHT”, filed on Jul. 22, 2010.

### BACKGROUND

Light Emitting Diode (LED) technology has made significant gains in recent years. The efficiency and light output of LED's has increased exponentially since the 1960's, with a doubling occurring about every 36 months. As a result, LED technology can now be successfully deployed for grow light applications, to provide high-efficiency, low cost, safe and long-lasting grow light solutions. However, the performance of LED grow lights varies, and there is an ongoing need in the grow light industry for high-performance grow lights that maximize photosynthesis, plant growth and flowering.

### SUMMARY

High performance LED lights and methods of manufacturing high performance LED lights are disclosed. Features of an example light may include, inter alia, LED elements with acute angle lenses, and LED distributions that optimize light intensity over a desired grow area, at wavelengths that maximize photosynthesis, plant growth and flowering. The light may also optionally provide for visibility of plant growth and the work area.

In some embodiments, an LED light may comprise a modular light-engine design. The modular light-engine design may be leveraged in manufacturing and servicing processes disclosed herein. High performance LED lights may comprise stacked-lens technologies disclosed herein. Also, LED lights may be configured for aquarium and home and commercial lighting applications as disclosed herein. Further aspects and embodiments are described below.

### BRIEF DESCRIPTION OF THE DRAWINGS

FIG. 1 illustrates side and bottom views of an example high-performance LED grow light.

FIG. 2A illustrates two example light engines comprising groups of LED elements positioned on a matrix mappable to a grow light surface.

FIG. 2B illustrates six example light engines comprising groups of LED elements positioned on a matrix mappable to a grow light surface.

FIG. 2C illustrates example light engine modules.

FIG. 2D illustrates an example high-performance LED light comprising one or more removable light engine modules.

FIG. 2E illustrates an example high-performance LED light comprising one removable light engine module.

FIG. 2F illustrates top and bottom views of an example high-performance LED light comprising four removable light engine modules.

FIG. 2G illustrates top and bottom views of an example high-performance LED light comprising configured for low power consumption.

FIG. 2H illustrates example heat radiating element configurations for heat sinks.

FIG. 3A illustrates an example LED element and an example grow area produced by an acute angle lens.

FIG. 3B illustrates an example LED element configured with a stacked lens, and an example grow area produced by the stacked lens.

FIG. 3C illustrates an example multi-element lens configured for use with a light engine.

FIG. 4 illustrates side and top views of an example high-performance LED grow light arranged as a vertical tower.

FIG. 5A illustrates an example light engine as may be included in a LED grow light configured for aquarium applications.

FIG. 5B illustrates an example controller configured for independent control of LED elements in a light engine, as may be included in a LED light configured for aquarium applications as well as the various other high-performance LED lights disclosed herein.

FIG. 6 illustrates an example light engine as may be included in a high-performance LED light configured for environmental lighting applications.

### DETAILED DESCRIPTION

The illustrative embodiments provided herein are not meant to be limiting. Other embodiments may be utilized, and changes may be made, without departing from the spirit or scope of the subject matter presented here. It will be understood that aspects of the present disclosure may be arranged, substituted, combined, and designed in a wide variety of different configurations.

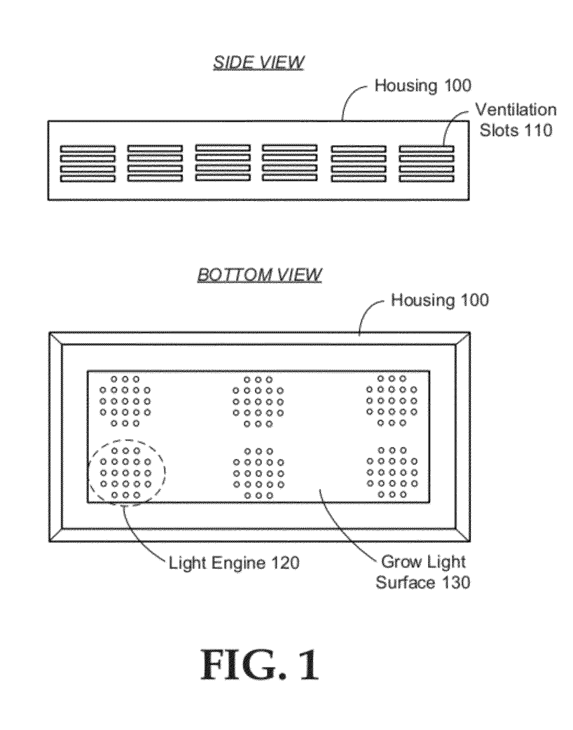

FIG. 1 illustrates side and bottom views of an example high-performance LED grow light. The side view shows a housing 100 with ventilation slots 110 allowing for cooling the grow light during operation. The bottom view shows the housing 100 and a plurality of LED elements arranged in a plurality of groups, referred to as “light engines” 120. The light engines 120 are positioned on a grow light surface 130.

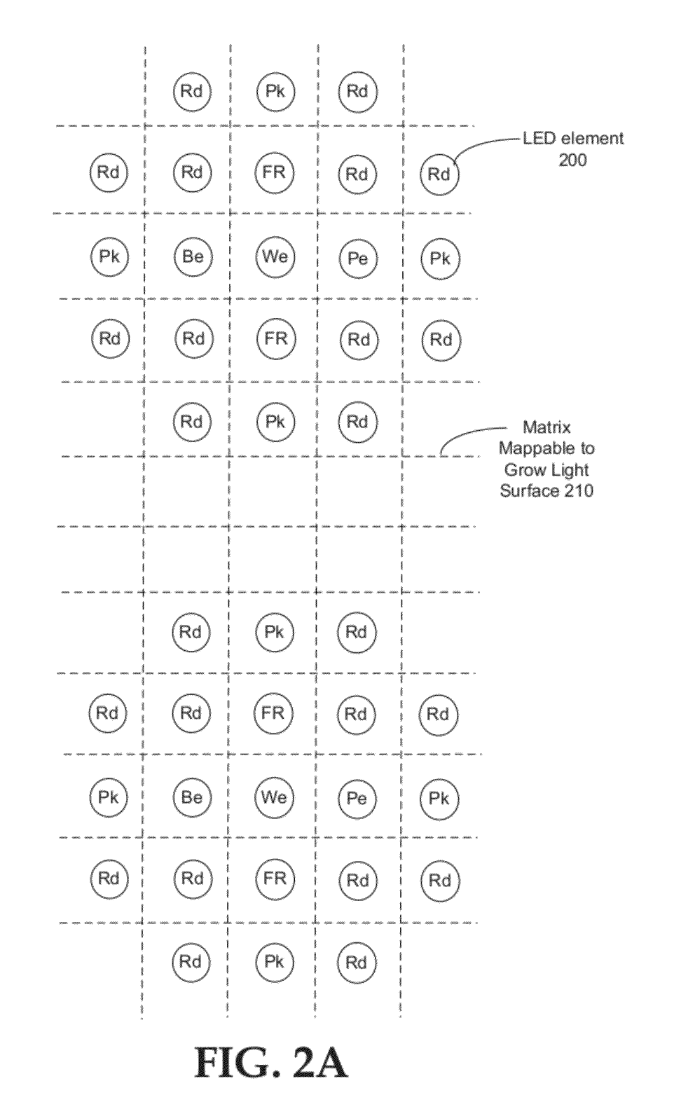

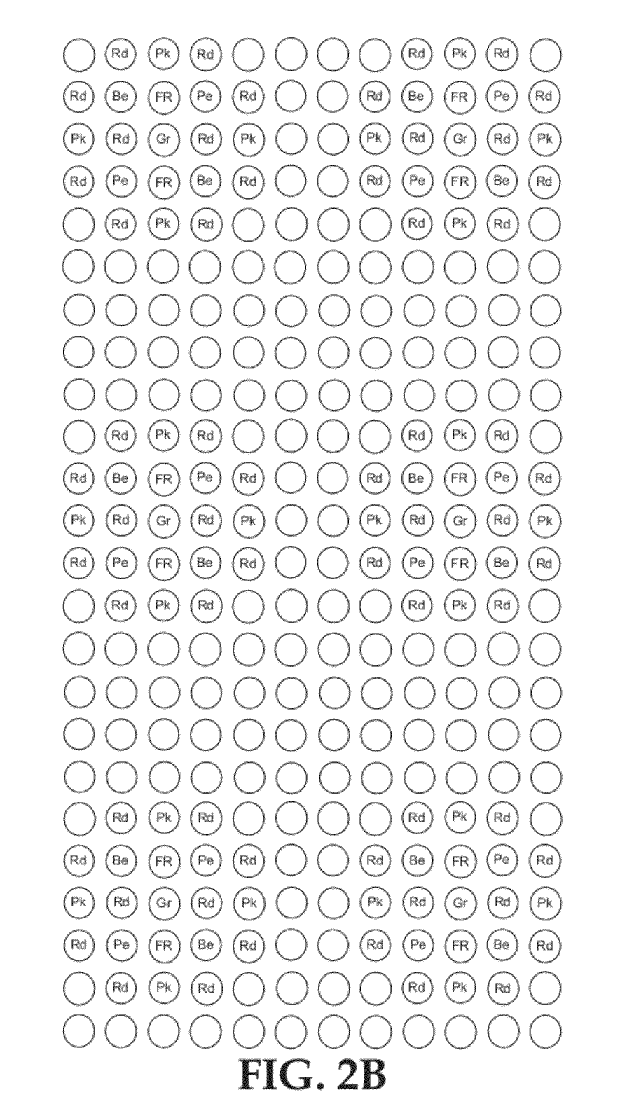

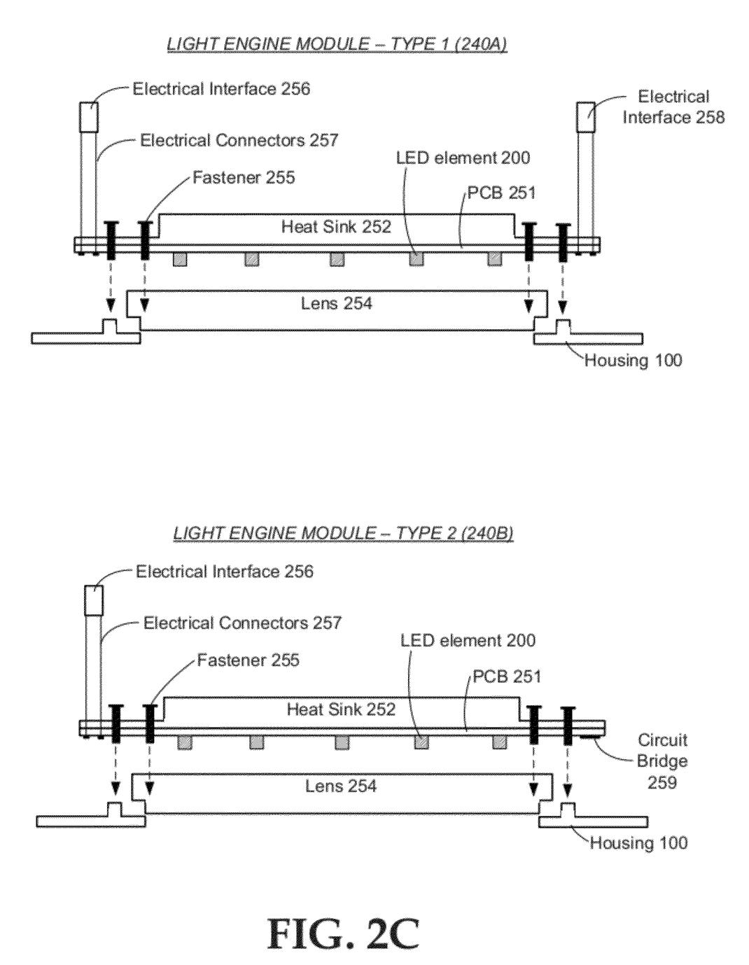

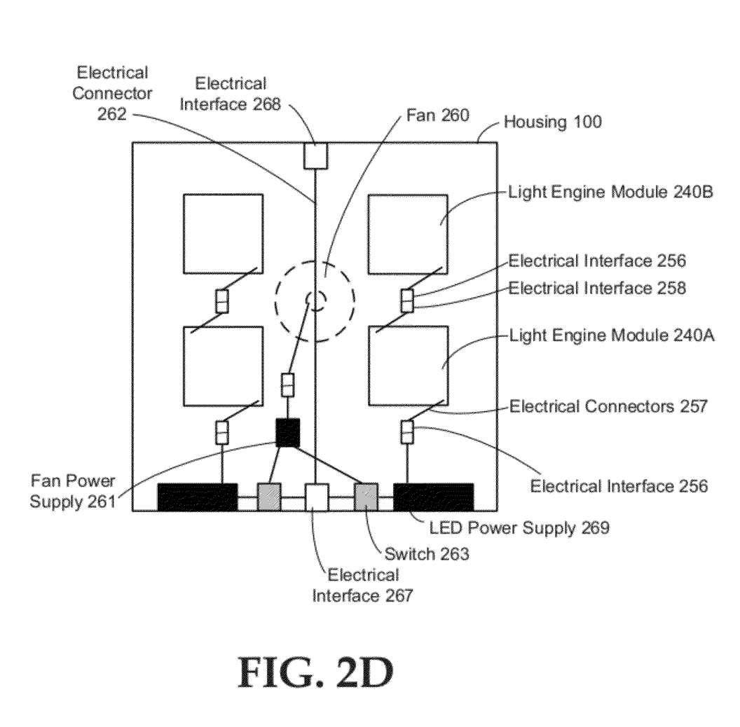

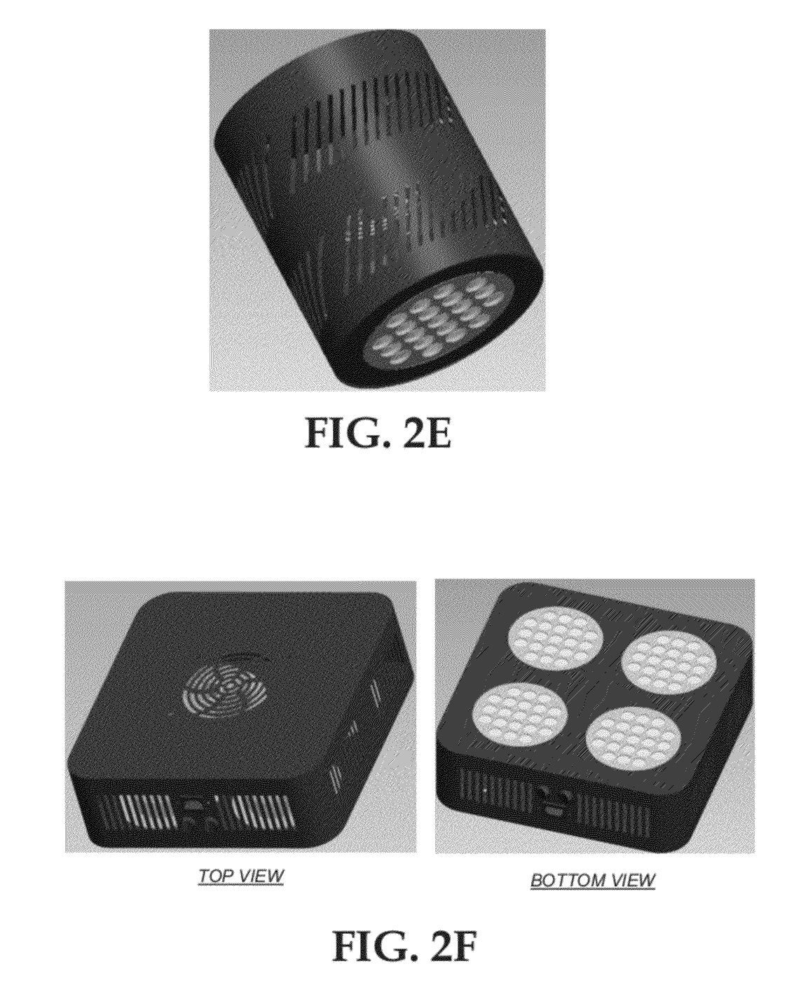

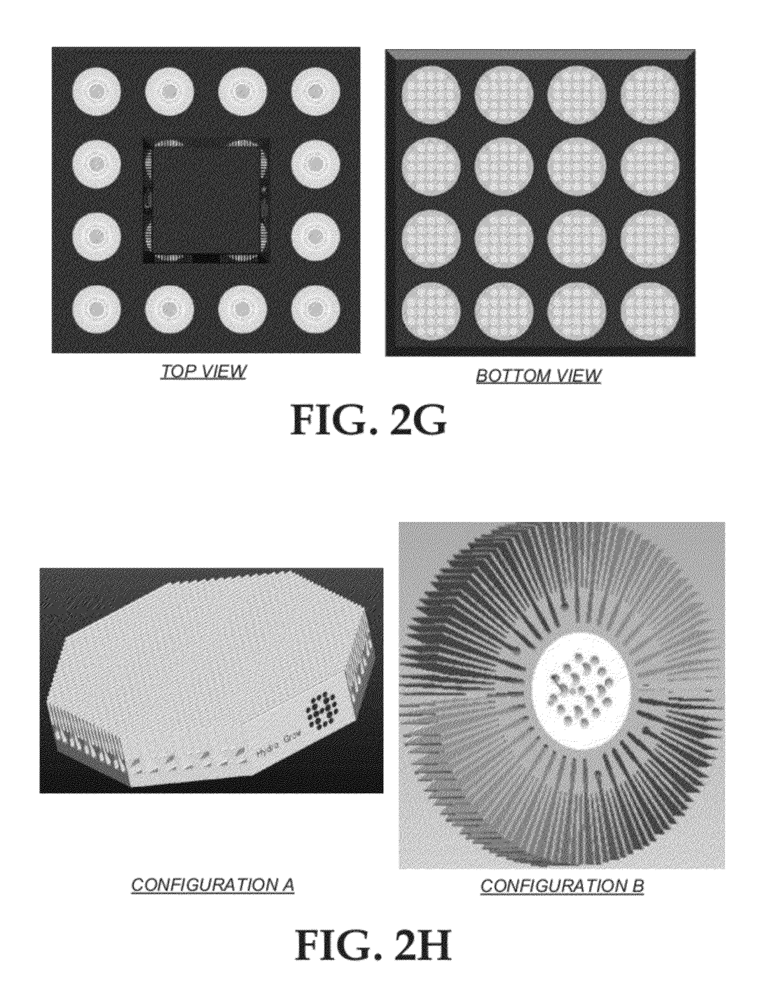

FIG. 2A illustrates two example light engines comprising groups of LED elements 200 positioned on a matrix mappable to a grow light surface 210. The example light engines comprise identical total numbers of LED elements, and identical numbers of LED elements of each of a plurality of different wavelengths. Each LED element 200 may comprise, for example, a one Watt, one-chip LED, a two Watt, two-chip LED, or a three Watt, three-chip LED.

In FIG. 2A, the total number of LED elements 200 in a light engine is 21, with 12 LED elements of Rd wavelengths, 4 LED elements of Pk wavelengths, 2 LED elements of FR wavelengths, 1 LED element of Be wavelengths, 1 LED element of Pe wavelengths, and 1 LED element of We wavelengths. The identified wavelengths may be characterized as substantially within the following ranges:

Rd (Red): wavelengths in the 650-670 nm range

Pk (Pink): wavelengths in the 630-650 nm range

FR (Far Red): wavelengths in the 730-750 nm range

Pe (Purple): wavelengths in the 430-450 nm range

Be (Blue): wavelengths in the 460-480 nm range

Gr (Green): wavelengths in the 500-550 nm range

DP (Deep Purple): wavelengths in the 400-420 nm range

We (White—6500K): multi-wavelength LED producing light with a color temperature of approximately 6500K. In this context, the term “approximately” allows a margin of error of plus or minus 10 K.

Wt (White—3000K): multi-wavelength LED producing light with a color temperature of approximately 3000K.

Wi (White—12000K): multi-wavelength LED producing light with a color temperature of approximately 12000K.

Note the while the light engines of FIG. 2A do not include Gr, DP, Wt, or Wi LED elements, such LED elements may be included in various embodiments, and example embodiments including such LED elements are described herein in connection with various other figures. Gr, Wt, and Wi LED elements may serve similar purposes as We LED elements discussed in FIG. 2A, in addition to supporting photosynthesis. Gr, Wt, and Wi LEDs may be used in place of We LEDs in some configurations.

The illustrated light engines may be modified in some embodiments, for example by removing LED elements of certain wavelengths, and optionally placing the removed LED elements elsewhere on the grow light surface. In order to achieve a light engine that promotes photosynthesis for many varieties of plants, in some embodiments the plurality of different wavelengths represented in a light engine may comprise any two or more of: a wavelength in the 430-450 nm range, a wavelength in the 460-480 nm range, a wavelength in the 500-550 nm range, a wavelength in the 630-650 nm range, a wavelength in the 650-670 nm range, a wavelength in the 730-750 nm range, and a multi-wavelength white light wavelength distribution.

For example, in some configurations, a light engine may comprise LED elements of each of a plurality of different wavelengths, including one LED with a wavelength of approximately 440 nm (a Pe wavelength), one LED with a wavelength of approximately 470 nm (a Be wavelength), five LED's with a wavelength of approximately 640 nm (a Pk wavelength), twelve LED's with a wavelength of approximately 660 nm (an Rd wavelength), and two LED's with a wavelength of approximately 740 nm (a FR wavelength). LEDs with We wavelengths may be optionally placed elsewhere on the grow light surface, outside of the light engine groups.

In another configuration, a light engine may comprise LED elements of each of a plurality of different wavelengths, including 9 Rd LEDs, 4 Pk LEDs, 4 We LEDs, 2 FR LEDs, and 2 Be LEDs.

In some embodiments it may be advantageous to produce light engines with differing numbers of LED elements, while keeping a same ratio of represented wavelengths. Thus for example a light engine larger than those illustrated in FIG. 2A may be produced while maintaining approximately 4.8% wavelengths in the Be range, 4.8% wavelengths in the Pe range, 19% wavelengths in the Pk range, 57.1% wavelengths in the Rd range, 9.5% wavelengths in the FR range, and 4.8% multi-wavelength white light LEDs. The term “approximately” is used in this context to generally allow a margin of error of plus or minus 1%.

Light engines may comprise any total number of LED elements, arranged in any shape or pattern. Square, triangular, and rectangular light engines may be configured in some embodiments, any of which may comprise any number of LED elements depending on the desired wavelengths to be included in the light engine. Many plants deliver maximum yield and flowering times with 75% red light between 600-700 nm, 15% blue light in the 400-500 nm range, and 10% green light between 500-600 nm. Therefore, light engines generally containing a mixture of LEDs that achieve these percentages may be advantageous in some configurations. The light engines disclosed in FIG. 2A contain 75% red light between 600-700 nm, and 15% blue light from 400-500 nm, accounting for the white LED's which have a primary output between 400-500 nm, and also extend into the green 500-600 nm region.

Light engines including FR LED elements (730-750 nm) in conjunction with Rd (660 nm red) may produce photosynthesis rates above light engines that include either of these wavelengths alone. Also, Gr LEDs may result in faster flowering times and increased quantum yields for certain agricultural crops, such as tomatoes.

In general, photosynthesis relies on four primary wavelengths in order for Chlorophyll A and B to function at their optimum levels. These wavelengths are found at 439 nm, 469 nm, 642 nm, and 667 nm for most terrestrial plants. In some embodiments, LED's included in a light engine may be selected to match one or more of these wavelengths as closely as possible. While a 450 or 460 nm LED may be cheaper and more common than a 440 or 470 nm LED, and a 620 or 630 nm LED may be cheaper and more common than a 640 nm LED, the use of the most effective wavelengths for photosynthesis results in a higher performance grow light. LEDs with the most effective wavelengths for photosynthesis may be selected for light engines in a high performance grow light based on photosynthesis properties of a class of plants, or based on photosynthesis properties of specific plant species in some embodiments.

LED output bands may also be considered in selecting LED elements for use in a light engine. Many LED elements produce an output band that is about 30 nm wide, with a peak at the design wavelength that falls to zero at the edges of the band. While in general, the peak output wavelength(s) of LED elements in a light engine should coincide with the optimal wavelengths for photosynthesis, the off-peak wavelengths may also be considered, especially in the case of multi-frequency white LEDs.

LED element wavelengths within a light engine and/or in auxiliary LED elements on a grow light surface may include wavelengths designed to allow the gardener to see his/her plants and/or surrounding work area as they would normally appear in sunlight. Certain wavelengths of the white LEDs in the light engines of FIG. 2A accomplish this. In general, green reflected light allows visual monitoring of a plant's health, and checking for pests or deficiencies.

In FIG. 2A, the example light engines comprise identical distributions of LED elements having each of the different wavelengths. The LED elements are distributed in an octagonal pattern comprising an Rd, a Pk, and an Rd in the first row, an Rd, and Rd, a FR, an Rd and an Rd in the second row, a Pk, a Be, a We, a Pe, and a Pk in the third row, an Rd, and Rd, a FR, an Rd and an Rd in the fourth row, and an Rd, a Pk, and an Rd in the fifth row.

A light engine may also be configured with another distribution of LED elements. For example, the light engine described above, including 9 Rd LEDs, 4 Pk LEDs, 4 We LEDs, 2 FR LEDs, and 2 Be LEDs, may comprise an Rd, a Pk, and an Rd in the first row, an Rd, a We, a FR, a We, and an Rd in the second row, a Pk, a Be, an Rd, a Be, and a Pk in the third row, an Rd, a We, a FR, a We, and an Rd in the fourth row, and an Rd, a Pk, and an Rd in the fifth row.

The light engine described above, including 1 Be LED, 1 Pe LED, 5 Pk LED's, 12 Rd LED's, and 2 FR LED's may comprise an Rd, a Pk, and an Rd in the first row, an Rd, an Rd, a FR, an Rd and an Rd in the second row, a Pk, a Be, a Pk, a Pe, and a Pk in the third row, an Rd, an Rd, a FR, an Rd and an Rd in the fourth row, and an Rd, a Pk, and an Rd in the fifth row. It will be appreciated that numerous other distributions of LEDs are possible.

In some embodiments, light engines may be positioned by separating them by at least one row or at least one column of the matrix 201. For example, the light engines of FIG. 2A are separated by two rows. Spreading the light engines in this manner improves efficiency of the grow light by allowing the light engines to deliver an appropriate amount of light to a grow area, without wasting energy by delivering light beyond a photosynthetic saturation point of a plant.

FIG. 2B illustrates an example high-performance light configured with six example light engines, each light engine comprising groups of LED elements positioned on a matrix mappable to a grow light surface. The six light engines are identical, and are separated by two rows of a matrix in one direction (parallel to a first axis of the matrix), and four rows of the matrix in the other direction (parallel to a second axis of the matrix). In FIG. 2B, each light engine comprises 2 Be LED's, 2 Pe LED's, 4 Pk LED's, 10 Rd LED's, 2 FR LED's, and 1 Gr LED. Each light engine may comprise an Rd, a Pk, and an Rd in the first row, an Rd, a Be, a FR, a Pe and an Rd in the second row, a Pk, an Rd, a Gr, an Rd, and a Pk in the third row, an Rd, a Pe, a FR, a Be and an Rd in the fourth row, and an Rd, a Pk, and an Rd in the fifth row, to produce approximately 9.5% wavelengths in the Be range, 9.5% wavelengths in the Pe range, 19% wavelengths in the Pk range, 48% wavelengths in the Rd range, 9.5% wavelengths in the FR range, and 4.8% wavelengths in the Gr range.

It should be emphasized that while various specific light engine configurations are disclosed herein, those of skill in the art will appreciate, with the benefit of this disclosure, that other light engine configurations may be made in accordance with the teachings provided herein. The technology permits a wide variety of configurations and light engines of differing numbers of LED's, differing shapes, and differing patterns may be made. Some grow lights may provide a plurality of identical light engines as illustrated in FIG. 2B, while others may provide two or more different light engine configurations within a single grow light.

FIG. 2C illustrates example light engine modules in accordance with some embodiments of this disclosure. FIG. 2C provides two different light engine module configurations, referred to herein as type 1 (240A) and type 2 (240B). Both light engine module configurations 240A and 240B may comprise a Printed Circuit Board (PCB) 251, LED elements 200, an electrical interface 256 and connectors 257, heat sink 252, lens 254, and fasteners 255. The type 1 light engine module 240A includes a second electrical interface 258, and the type 2 light engine module 240B includes a circuit bridge 259. In some embodiments, an LED light may include light engine modules of both type 1 (240A) and type 2 (240B). In some embodiments, an LED light may include light engine modules of only type 2 (240B). The term “light engine module” as used herein refers to a light engine module of either configuration 240A or 240B, unless a specific configuration is specified.

In both light engine module configurations 240A and 240B, the LED elements 200 may form a light engine according to any of the various embodiments described herein. The electrical interface 256 may be coupled to the PCB 251 via electrical connectors 257, and the PCB 251 may comprise circuit traces forming electrical connections between the electrical connectors 257 and LED elements 200. In light engine modules of type 2 (240B), a circuit bridge 259 may electrically connect circuit trace segments on the PCB 251, so that a complete circuit is formed between the electrical connectors 257. In light engine modules of type 1 (240A), each of the electrical connectors 257 coupled to electrical interface 256 may connect to a separate circuit trace segment on the PCB 251, and the separate circuit trace segments may each connect to separate electrical connectors that lead to electrical interface 258.

Light engine modules may be configured to be inserted and removed from an LED light housing 100. In some embodiments, the lens 254 may include a lip that is sized and shaped to fit in an opening formed in the housing 100. The electrical interfaces 256 and 257 may comprise clip-style, or other manually connectable and disconnectable interfaces. Light engine modules may also comprise a set of fasteners 255 that couple the light engine module with corresponding fastener guides disposed on the housing 100. In FIG. 2C, the outer fasteners 255 couple the light engine modules with corresponding fastener guides disposed on the housing 100. Any number of fasteners 255 may be used for this purpose. In some embodiments, the base plate of the heat sink 252 and the PCB 251 may be square in shape, and may be coupled with the housing 100 via two outer fasteners 255, which are at opposite sides of a diagonal bisecting the square.

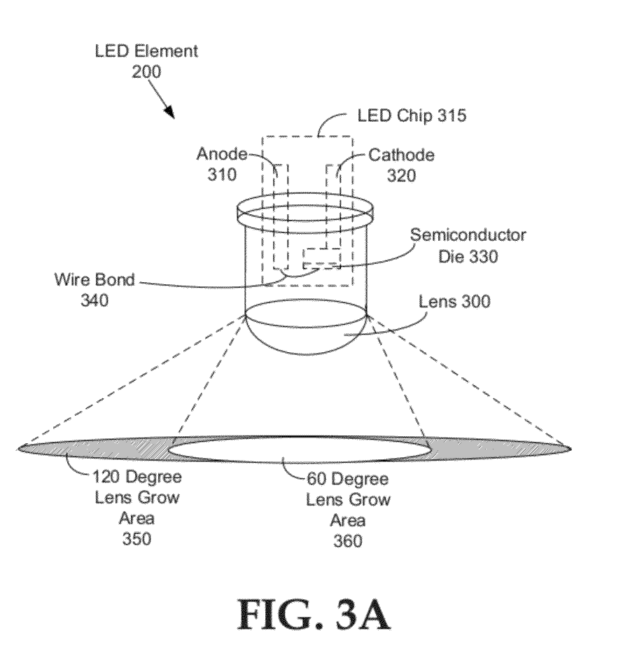

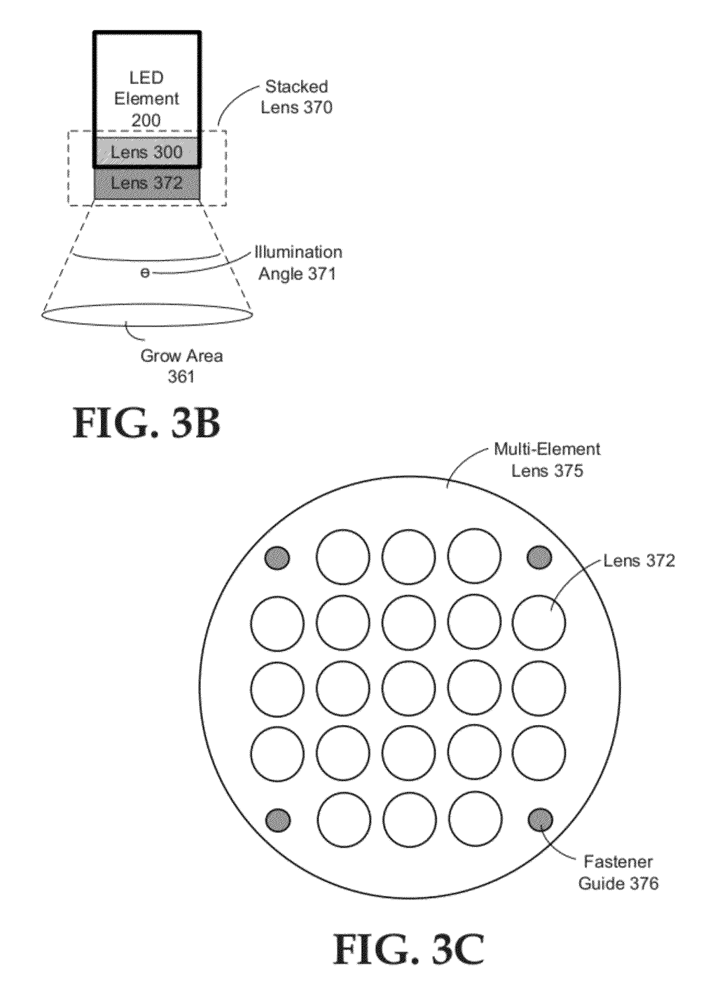

Lens 254 may be included in stacked-lens embodiments according to FIG. 3B and FIG. 3C. Each LED element 200 may include a first lens, e.g., lens 300 in FIG. 3A, and lens 254 may provide second lenses for some or all of the LED elements 200 of a light engine module, to achieve a desired grow area/illumination angle for the light engine module and corresponding LED light. In single lens embodiments, the lens 245 may optionally be omitted from a light engine module, or replaced be a transparent protective covering. In some embodiments, a lens 254 may be included in an LED light separately from the light engine module(s), e.g., attachable underneath the housing 100 or integrated into the housing 100.

A light engine module may include fasteners 255 and/or fastener guides configured to attach the heat sink 252, PCB 251, and/or lens 254 together as a single unit. The inner set of fasteners 255 in FIG. 2C may for example screw into fastener guides inside the lens 254. Any number of fasteners 255 may be used for this purpose. In some embodiments, four inner fasteners 255 may couple the heat sink 252, PCB 251, and lens 254, with one inner fastener at each corner of the square base plate of the heat sink 252 and PCB 251.

In some embodiments, the heat sink 252 may comprise a base plate with a bottom surface that is affixed to the PCB 251, and a heat radiating element that extends opposite the PCB 251. In some embodiments, the base plate of the heat sink 252 and PCB 251 are square in shape, when viewed from the top or bottom, while the heat radiating element of the heat sink 252 and the lens 254 are circular in shape. The diameter of the heat radiating element of the heat sink 252, the diameter of the lens 254, and the length of a side of the square base plate of the heat sink 252 and PCB 251 may be substantially equal, where “substantially equal” in this context refers to the smallest of the components having a diameter/length of side measurement that is at least 90% of the largest of the components.

FIG. 2D illustrates an internal view of an example high-performance LED light comprising one or more removable light engine modules in accordance with some embodiments of this disclosure. The illustrated example LED grow light includes a housing 100 configured to house one or more removable light engine modules 240A, 240B. The light further includes external electrical interfaces 267, 268, switches 263, LED power supplies 269 configured to connect to the light engine modules, and a fan power supply 261 and fan 260.

In FIG. 2D, external electrical interface 267 may connect the LED grow light to external power, e.g. via an electrical cord configured to plug into interface 267 at one end and a wall-type electrical socket at the other end. The external electrical interface 267 is electrically connected to external electrical interface 268 via electrical connector 262. Electrical interface 268 may be configured to supply power to a next LED grow light, e.g. via an electrical cord configured to plug into interface 268 at one end and an interface such as 267, on a next LED grow light, at the other end.

In some embodiments, the external electrical interfaces 267, 268 may comprise a male type interface, e.g., 267, and a female type interface, e.g., 268, allowing multiple LED lights to be connected in series with appropriate electrical cords. Embodiments comprising one single external electrical interface, e.g., by omitting interface 268, or more than two external electrical interfaces, e.g. by including additional interfaces 268, are also feasible as will be appreciated.

Electrical interface 267 is also electrically connected to switches 263. The switches 263 may be externally operable to individually switch on and off the power to each LED power supply 269. Each switch 263 may also switch on and off the power to the fan power supply 261. In this configuration, turning “on” either switch 263 illuminates a subset of the light engine modules included in the LED light, an also operates the fan 260. Turning “on” both switches 263 illuminates all of the light engine modules included in the LED light, an also operates the fan 260.

The LED power supplies 269 operate separate subsets of the light engine modules included in the LED light. Each LED power supply 269 has electrical connectors (wires) leading to electrical interfaces that couple to light engine module electrical interfaces 256. Electrical interfaces 258 extend from each of the type 1 light engine modules 240A to couple with electrical interfaces 256 leading to each of the type 2 light engine modules 240A.

While FIG. 2D includes one type 1 light engine module 240A in each subset of light engine modules, it will be appreciated that in alternate configurations, any number of type 1 light engine modules 240A may be included between a LED power supply 269 and a type 2 light engine module 240B. Also, in some configurations the light may include only type 2 light engine modules 240B, each of which may connect directly to the LED power supply 269.

A configuration according to FIG. 2D is somewhat cleaner in design than configurations including only type 2 light engine modules 240B. However, configurations according to FIG. 2D have the disadvantage that if a type 2 light engine module 240B is removed from the light, then the connected type 1 light engine module 240A will not be on a complete circuit and will not be operable. To solve this problem, one or more circuit completion interfaces (not shown) may optionally be provided along with an LED light, or in response to a warranty repair or other service request. A circuit completion interface may connect to an electrical interface 258 to complete the circuit and allow operation of the type 1 light engine module 240A even if the type 2 light engine module 240B is removed. Incidentally, the removal of a type 1 light engine module 240A need not prevent operation of the connected type 2 light engine module 240B, because the type 2 light engine module 240B can be connected directly to the power supply 269. Alternatively, a user of the light may be instructed to leave a subset of light engine modules switched off until a removed light engine module is replaced.

The fan power supply 262 is connected via an electrical interface to the fan 260. In FIG. 2D, the light engine modules may be disposed on the floor of the housing 100 while the fan 260 is affixed to the ceiling of the housing 100.

In some embodiments, each of the illustrated electrical interfaces, e.g. interfaces 256, 258 and the various other illustrated interfaces may comprise attachable/detachable interfaces, such as clip-style interfaces configured for attaching and detaching without any special tools. This allows for easy removal of any of the light engine modules from the housing 100. The interface connecting the fan 260 to the fan power supply 261 may similarly be attachable/detachable in some embodiments.

The power supplies 269 and 262 may be configured to suit the power requirements of the subsets of light engine modules and fan. For example, for subsets of light engine modules comprising two light engine modules as illustrated in FIG. 2D, each of the power supplies 269 may for example receive a 100-240V Alternating Current (AC) input, and may be configured to supply a 55 W output to the subsets of light engine modules.

Methods for manufacturing and servicing LED lights may be configured to leverage modular properties disclosed in connection with FIG. 2C and FIG. 2D. For example, a variety of different size LED light housings according to FIG. 2D may be manufactured, including, e.g., a housing adapted for one light engine module, a housing adapted for four light engine modules arranged in a 2×2 square, a housing adapted for six light engine modules arranged in a 3×2 rectangle, a housing adapted for nine light engine modules arranged in a 3×3 square, a housing adapted for sixteen light engine modules arranged in a 4×4 square, and/or a housing adapted for eight light engine modules arranged in a 8×1 row. Light engine modules for each of the different housing sizes and shapes may be interchangeable, so that any light engine module may be inserted into any housing. This streamlines the manufacturing process and also improves serviceability of a LED light. Purchasers can remove and send back a faulty light engine module without the shipping cost and handling associated with a full light. The manufacturer can provide a replacement light engine module at lower cost than a full new light. Furthermore, the customer can continue to use an LED light while one or more of the light engine modules are removed.

FIG. 2E and FIG. 2F provide external views of example high-performance LED lights. FIG. 2E illustrates an example light comprising one removable light engine module, and FIG. 2F illustrates top and bottom views of an example light comprising four removable light engine modules. The light engine module/modules comprising the LED elements of FIG. 2E and FIG. 2F can be removed from the housings.

FIG. 2G illustrates top and bottom views of an example high-performance LED light comprising configured for low power consumption. The top view illustrates the top of a thin-profile housing comprising a raised cage in the middle thereof. The thin-profile housing comprises openings for heat radiating elements of the various heat sinks associated with light engines within the light. The raised cage portion includes ventilation slots for air transfer to the heat radiating elements located underneath the raised cage portion. External interfaces such as 267, 268 may be disposed in the raised cage portion, along with switches and/or other controls for the light. The bottom view illustrates the bottom of the thin-profile housing, comprising openings for the various light engines associated with the heat radiating elements shown in the top view.

In some embodiments, a high-performance LED light comprising configured for low power consumption, such as illustrated in FIG. 2G, may use all or substantially all 0.5 W LED elements. Some embodiments may omit cooling fans, further reducing energy consumption and also eliminating the noise associated with fan operation. Some embodiments may furthermore have a non-adjustable power supply, while other embodiments may have an adjustable power supply that can be dimmed or brightened by the user, allowing further energy savings under the control of the user. FIG. 2G illustrates an embodiment comprising 16 light engine modules, however other embodiments according to FIG. 2G may be equipped with any number of light engines/light engine modules, for example 4, 6, 8, or 12 light engine modules.

FIG. 2H illustrates example heat radiating element configurations for heat sinks. Configuration A comprises an octagon shaped heat radiating element, with a solid bottom portion and longitudinally arranged fins. The fins alternate between flat vertical fins and branching pitchfork fins. Configuration B comprises an internal hub attached to radiating fins, where fin bases each branch away from the central hub into subsets of thin fins.

In some embodiments, a heat sink 252 may comprise a heat radiating element according to configuration A or B may be affixed to a base plate for use in a light engine module. Example heat radiating elements may be made of aluminum and/or copper. In some embodiments, an aluminum heat radiating element may be used with a copper base plate, or an aluminum heat radiating element and base plate and base plate may be configured with a copper insert, for example, a 3 mm thick copper insert that is affixed between the heat sink 252 and PCB 251.

The diameter of a heat radiating element may correspond to the diameter of a light engine for which the heat radiating element is designed. For example, the heat radiating element and light engine may have approximately equal diameters, such as where the smaller diameter is 75% or more of the larger diameter. The thickness of a heat radiating element may correspond to the power of the LED elements used in a light engine for which the heat radiating element is designed. Example heat radiating elements may be approximately 8 mm, 15 mm, 20 mm, or 30 mm thick, where the term “approximately” in this context includes size ranges of plus or minus 25%. In some embodiments, a 15 mm heat radiating element may be used with a light engine module comprising 1 Watt LEDs, and a 20 mm heat radiating element may be used with a light engine module comprising 3 Watt LEDs.

FIG. 3A illustrates an example LED element 200 and an example grow area produced by an acute angle lens. The LED element 200 may comprise a lens 300, and an LED chip 315 comprising an anode 310, a cathode 320, a semiconductor die 330 and a wire bond 340. The LED produces light by applying a potential difference across the semiconductor die 330 via the anode 310 and wire bond 340 and cathode 320. The potential difference causes the semiconductor die 330 to release light of a selected wavelength or wavelengths.

A 120° lens will cause an LED element to illuminate a grow area 350 at a first intensity level, while an acute angle lens, defined herein as a lens having an angle less than 120°, will cause an LED element to illuminate a grow area smaller than that illuminated by the 120° lens, with an intensity greater than the 120° lens. For example, a 60° lens will illuminate a grow area 360 with greater intensity than the larger grow area 350 illuminated by the 120° lens.

In some embodiments, a high performance LED grow light may comprise a plurality of LED elements on a grow light surface, wherein at least one of the plurality of LED elements comprises an acute angle lens defining a grow area illuminated by the LED element. In some embodiments, substantially all of the LED elements may comprise acute angle lenses. In this context, the term “substantially all” refers to 75% or more. In some embodiments, acute angle lenses in substantially all of the LED elements may comprise 60° lenses. In some embodiments, acute angle lenses in substantially all of the LED elements may comprise lenses with angles less than 60°. Furthermore, the plurality of LED elements may comprise LED elements of each of a plurality of different wavelengths, as described herein.

A method of manufacturing a high performance LED grow light disclosed herein may include, inter alia, defining a light engine comprising a total number of LED elements and a defined number of LED elements at each of a plurality of wavelengths, wherein the defined number of LED elements at each of a plurality of wavelengths are defined to optimize photosynthesis of a plant. A grow area for the LED grow light may be identified, and a plurality of light engines may be positioned on a grow light surface to optimize illumination of the grow area according to the photosynthesic needs of the plant. In some embodiments, the LED's of the light engine may comprise acute angle lenses, as described herein. Also, the number of LED elements at each of the plurality of wavelengths may be further defined by wavelengths that facilitate visual inspection of the plant. For example, some of the wavelengths of the multi-wavelength white light LED's disclosed herein may not meaningfully contribute to photosynthesis, but may allow for easier visual inspection of a plant under the grow light, as well as any work area underneath the grow light.

In some embodiments, a high performance LED light may comprise LED elements 200 comprising two or more chips 315 under a lens 300. Such embodiments can yield efficiency gains in some configurations. For example, a single 5 W LED chip 315 driven at 1000 mA is less efficient, in terms of lumens per 100 mA, than an equivalent number of 1 W LED chips. In some embodiments, an LED element 200 may comprise two 3 W LED chips under a lens 300, to implement a 5 W LED element 200 that consumes 1000 mA divided to 500 mA per chip. Each of the two 3 W LED chips can handle 700 mA, and at 500 mA the 3 W LED chips are only slightly less efficient than an equivalent number of 1 W LED chips. Also, the amount of heat generated at 500 mA per chip is less that the heat that would be generated by a chip drawing 1000 mA.

FIG. 3B illustrates an example LED element configured with a stacked lens, and an example grow area produced by the stacked lens in accordance with some embodiments of this disclosure. An LED element 200 generally includes a lens 300 as seen in FIG. 3A. In some embodiments, an additional lens 372 may be stacked over lens 300 to produce a stacked lens configuration 370. The combined lenses 300, 372 define an illumination angle 371 for the LED element 200, and corresponding grow area 361.

In some embodiments, a LED light may comprise a plurality of LED elements 200 on a lighting surface 130 as shown for example in FIG. 1, and two or more lenses stacked in a light path of each of the plurality of LED elements 200, so that light produced by an LED element 200 first passes through a first lens 300, and subsequently passes through at least one second lens 372, wherein the combined lenses 300, 372 define an illumination angle 371 for the LED element 200. The plurality of LED elements 200 may be arranged in any of the various light engine groups described herein. The illumination angle produced by combined lenses for one or more of a plurality of LED elements within a light engine group, or within an LED light in general, may be anything from 0-180 degrees. Illumination angles of 60, 90, and 120 degrees may be advantageous in many applications. For most grow light applications, a preferred embodiment may employ an illumination angle near 90 degrees, e.g., within 80-100 degrees, however other illumination angles may be advantageous in some circumstances. In some embodiments, the first lens 300 on each of the LED elements within a grow light may be a 60 degree lens or a 90 degree lens, and a second lens 372 disposed over each of the LED elements may be an 80 degree lens or a 90 degree lens. For example, the first lens 300 on each of the LED elements within a grow light may be a 60 degree lens, and the second lens 372 disposed over each of the LED elements may be an 80 degree lens. The first lens 300 on each of the LED elements within a grow light may be a 90 degree lens, and the second lens 372 disposed over each of the LED elements may be an 80 degree lens. The first lens 300 on each of the LED elements within a grow light may be a 60 degree lens, and the second lens 372 disposed over each of the LED elements may be a 90 degree lens. The first lens 300 on each of the LED elements within a grow light may be a 90 degree lens, and the second lens 372 disposed over each of the LED elements may be a 90 degree lens.

LED elements within a light engine group, or within a LED light in general, may include LED elements of each of a plurality of different wavelengths, as disclosed herein. In some embodiments, combined lenses such as 300, 372 for LED elements of a first wavelength, e.g., for Rd LEDs in a light engine, may all define a first illumination angle, e.g., one of 60, 90, or 120 degrees. Combined lenses such as 300, 372 for LED elements of a second wavelength, e.g., for FR LEDs in a same light engine, may define a second illumination angle, e.g., one of 60, 90, or 120 degrees, where the second illumination angle is different from the first illumination angle. This allows an LED light to produce different desired light intensities at different wavelengths, as may be useful in some embodiments.

FIG. 3C illustrates an example multi-element lens configured for use with a light engine in accordance with some embodiments of this disclosure. In some embodiments, a multi-element lens 375 may be configured from a single piece of glass or plastic. For example, multi-element lens 375 may be constructed from a single piece of optics grade polymethyl methacrylate (PMMA) acrylic. The multi-element lens 375 may comprise a plurality of individual lenses such as 372 formed therein. The plurality of individual lenses such as 372 may be positioned to fit over one or more of the LEDs in a light engine group. The multi-element lens 375 may for example attach to a light engine module, e.g., as lens 254 illustrated in FIG. 2C, and may provide an individual lens for each of the LED elements in a light engine module. In some embodiments, each of the LED elements 200 may comprise a first lens such as lens 300, and a multi-element lens 375 may provide second lenses 372 for each of the LED elements 200. A multi-element lens 375 may also comprise a fastener structure, such as fastener guides 376, for attaching and removing the multi-element lens 375 from a housing 100 or from other elements of a light engine module.

In some embodiments, the shape and internal engineering of each individual lens 372 within the 21-lens multi-element lens 375 may be independently calibrated for the specific wavelength and emitting angle of the LED beneath each individual lens 372. For example, six individual lens types for lens 372 may be created, so that each wavelength to be included in a light engine group such as illustrated in FIG. 2B has a unique lens type.

In some configurations, an LED light according to this disclosure may be configured with a single light engine module and a total of 21 LED lights, with four light engine modules and a total of 84 LEDs, with six light engine modules and a total of 126 LEDs, with eight light engine modules and a total of 168 LEDs, with nine light engine modules and a total of 189 LEDs, or with sixteen light engine modules and a total of 336 LEDs. Any of the above may be produced with all or substantially all one-Watt LEDs, all or substantially all three-Watt LEDs, and/or all or substantially all five-Watt LEDs. In this context, the term “substantially all” refers to 75% or more. Furthermore, any of the above may be produced, for example, with stacked lenses with 60 and/or 90 degree illumination angles. Also, in some embodiments, any of the above may be produced with low-power surface mount LEDs (SMD LEDs). For example, some embodiments according to FIG. 2G may optionally be made with SMD LEDs. SMD LEDs advantageously give off very little heat, can be very small, and have very low voltage and current requirements. The use of SMD LEDs allows for a thin-profile housing 100, for example a housing that is, for the most part, less than 2 inches thick. For example, 50% or more of the area seen in a top or bottom view of the housing may be less than 2 inches thick. The thin-profile housing may also comprise a thicker portion, e.g., a beam across the central area of the housing or a raised cage portion as shown in FIG. 2G, to provide structural stiffness and/or accommodate electronics included in the light.

In some configurations, a grow light according to this disclosure may comprise a housing approximately 16 inches long, 8.5 inches wide, and 3.5 inches thick, with a net weight of approximately 13 pounds. Sixty three (63) one-Watt high power LED's, with 60° lenses may be grouped into 3 light engines on the grow light surface. Each light engine may comprise one or more LED's with 440 nm wavelengths, 470 nm wavelengths, 640 nm wavelengths, and 660 nm wavelengths, and/or white and far red LEDs. The grow light may produce approximately 85% red, 10% blue, and 5% white light. Three 1.5 Watt fans may be positioned within the housing to cool the unit. In some embodiments, the fans may comprise dual ball bearing, 120 mm cooling fans. A 6 foot long standard 110 volt outlet power cable (or 220 volt for units to be sold outside the United States) may supply power to the unit. The unit may comprise an on/off switch and hangars for hanging the unit over a grow area. The optimal grow area may be about 12×18 inches, when the light is positioned about 6 inches over the plant canopy, with a maximum coverage area of about 18×24 inches achievable by raising the light.

In some configurations, a grow light according to this disclosure may comprise a housing approximately 19 inches long, 12.5 inches wide, and 3.5 inches thick, with a net weight of approximately 13 pounds. One hundred twenty six (126) one-Watt high power LED's, with 60° lenses may be grouped into 6 light engines on the grow light surface. Each light engine may comprise one or more LED's with 440 nm wavelengths, 470 nm wavelengths, 640 nm wavelengths, and 660 nm wavelengths, and/or white and far red LEDs. The grow light may produce approximately 85% red, 10% blue, and 5% white light. Six 1.5 Watt fans may be positioned within the housing to cool the unit. A 6 foot long standard 110 volt outlet power cable (or 220 volt for units to be sold outside the United States) may supply power to the unit. The unit may comprise an on/off switch and hangars for hanging the unit over a grow area. The optimal grow area may be about 18×30 inches, when the light is positioned about 12 inches over the plant canopy, with a maximum coverage area of about 24×36 inches achievable by raising the light.

In some configurations, a grow light according to this disclosure may comprise a housing approximately 19 inches long, 19 inches wide, and 3.5 inches thick, with a net weight of approximately 19 pounds. Three hundred forty five (3455) one-Watt high power LED's, with 60° lenses may be grouped into 16 light engines on the grow light surface, with nine single LEDs also positioned on the grow light surface. Each light engine may comprise one or more LED's with 440 nm wavelengths, 470 nm wavelengths, 640 nm wavelengths, and 660 nm wavelengths, and/or white and far red LEDs. The grow light may produce approximately 85% red, 10% blue, and 5% white light. Five 1.5 Watt fans may be positioned within the housing to cool the unit. A 6 foot long standard 110 volt outlet power cable (or 220 volt for units to be sold outside the United States) may supply power to the unit. The unit may comprise an on/off switch and hangars for hanging the unit over a grow area. The optimal grow area may be about 30×30 inches, when the light is positioned about 6 inches over the plant canopy, with a maximum coverage area of about 36×36 inches achievable by raising the light.

In some configurations, a grow light according to this disclosure may comprise a housing approximately 19 inches long, 19 inches wide, and 3.5 inches thick, with a net weight of approximately 17 pounds. Two hundred five (205) one-Watt high power LED's, with 60° lenses may be grouped into 9 light engines on the grow light surface, with four groups of four LEDs also positioned on the grow light surface. Each light engine may comprise one or more LED's with 440 nm wavelengths, 470 nm wavelengths, 640 nm wavelengths, and 660 nm wavelengths, and/or white and far red LEDs. The grow light may produce approximately 85% red, 10% blue, and 5% white light. Five 1.5 Watt fans may be positioned within the housing to cool the unit. A 6 foot long standard 110 volt outlet power cable (or 220 volt for units to be sold outside the United States) may supply power to the unit. The unit may comprise an on/off switch and hangars for hanging the unit over a grow area. The optimal grow area may be about 36×36 inches, when the light is positioned about 12 inches over the plant canopy, with a maximum coverage area of about 42×42 inches achievable by raising the light.

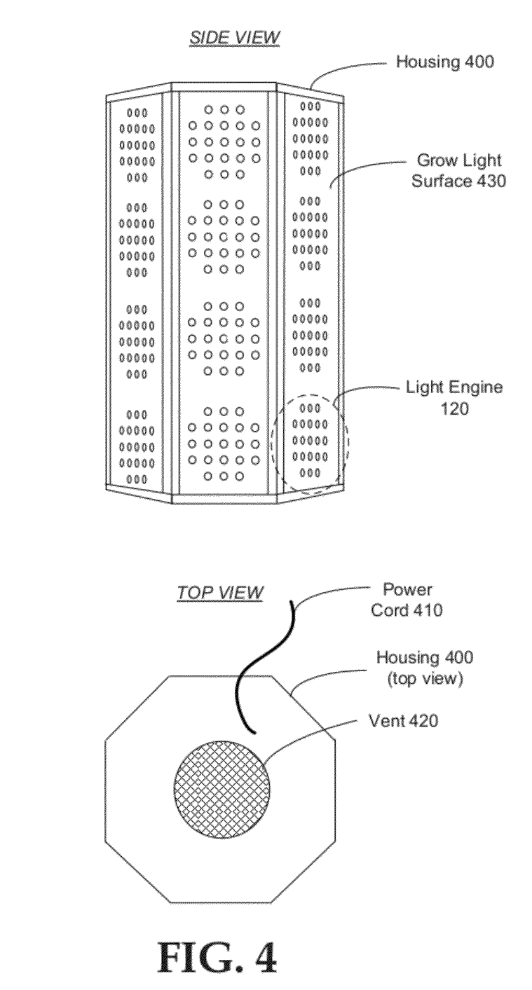

FIG. 4 illustrates side and top views of an example high-performance LED grow light arranged as a vertical tower. The tower may comprise, for example, a housing 400 that is arranged to stand vertically, to provide one or more vertically oriented grow light surfaces such as 430. Light engines such as 120, comprising a plurality of LED elements, may be arranged in a vertical orientation on one or more of the vertically oriented grow light surfaces 430. In some embodiments, the tower may comprise a plurality of side walls, each side wall comprising a grow light surface, the tower thereby emitting light outwardly around the full perimeter of the tower. For example, the tower may take a hexagonal shape as shown, thereby providing six vertical side walls. Each side wall may comprise a grow light surface and each grow light surface may comprise a plurality of light engines. A power cord 410 supplies power to the unit and a vent 420 allows one or more fans inside the unit to draw air through the unit for cooling.

In some configurations, a vertical grow light according to this disclosure may comprise, for example, a housing approximately 21 inches tall and 10.5 inches wide, with a net weight of approximately 35 pounds. Five hundred and four (504) one-Watt high power LED's, with 90° lenses may be grouped into 24 light engines on the six grow light surfaces, as illustrated in FIG. 4. Alternatively, additional luminosity may be achieved in tower configurations using a two Watt and three Watt (two chip and three chip) LED's. Each light engine may comprise one or more LED's with 440 nm wavelengths, 470 nm wavelengths, 640 nm wavelengths, and 660 nm wavelengths, and/or white and far red LEDs. The grow light may produce approximately 85% red, 10% blue, and 5% white light.

One or more fans may be positioned within the housing to cool the unit. A 6 foot long standard 110 volt outlet power cable (or 220 volt for units to be sold outside the United States) may supply power to the unit. The unit may comprise an on/off switch and hangars for hanging the unit over a grow area. The unit may also rest on the floor, with the vertical grow light surfaces extending upwards. The optimal grow area may be a volume extending from the grow light surfaces to about 36 inches therefrom and about 36 inches above and below the top and bottom of the grow light. The light may be designed for optimal positioning about 6-12 inches away from plants.

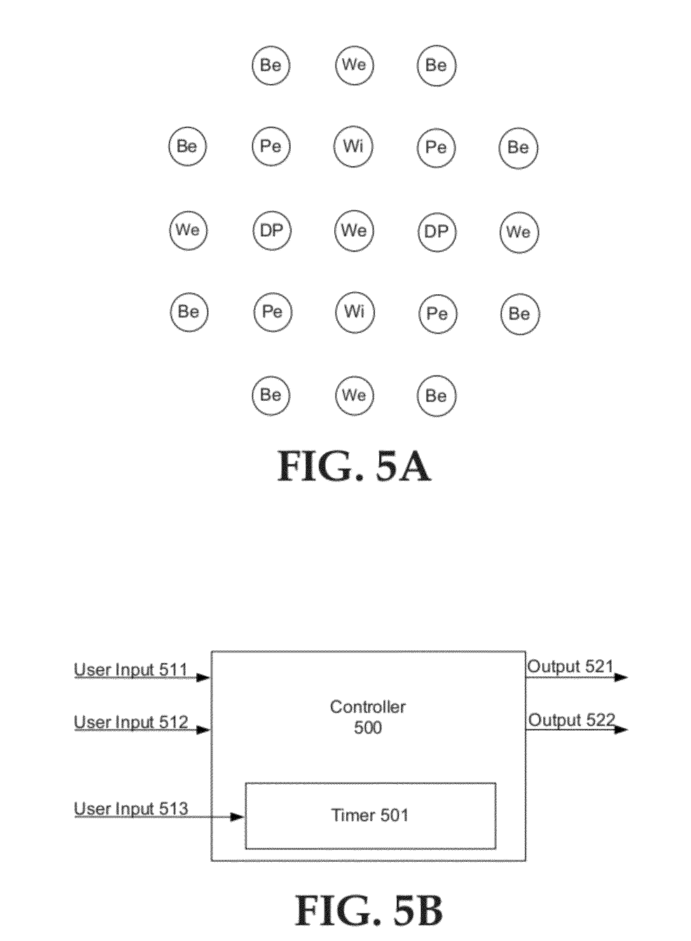

FIG. 5A illustrates an example light engine as may be included in a LED grow light configured for aquarium applications in accordance with some embodiments of this disclosure. In some embodiments, a light engine according to FIG. 5A may be adapted for use in an aquarium by including LED elements with two or more different wavelengths selected from the group comprising: wavelengths in the 430-450 nm range; a combination of wavelengths producing a color temperature of substantially 6500 Kelvin (K); a combination of wavelengths producing a color temperature of substantially 12000 K; wavelengths in the 400-420 nm range; and wavelengths in the 460-480 nm range. For example, the light engine illustrated in FIG. 5A comprises approximately 19% LED elements with wavelengths in the 430-450 nm range; 24% LED elements with a combination of wavelengths producing a color temperature of substantially 6500 Kelvin (K); 9.5% LED elements with a combination of wavelengths producing a color temperature of substantially 12000 K; 9.5% LED elements with wavelengths in the 400-420 nm range; and 38% LED elements with wavelengths in the 460-480 nm range.

In some embodiments, an LED grow light configured for aquarium applications may comprise all or substantially all LEDs with stacked lenses configured to produce a 60 degree illumination angle, to allow for deep water penetration in coral and other fish tanks. Of course, other lens designs and illumination angles may be applied in some embodiments.

FIG. 5B illustrates an example controller configured for independent control of LED elements in a light engine, as may be included in a LED grow light configured for aquarium applications, as well as the various other high-performance LED lights, in accordance with some embodiments of this disclosure. The controller 500 is configured to receive two or more user inputs 511, 512, 513, e.g., via dials, a touchscreen, a keypad, or other input device. User inputs 511 and 512 may comprise intensity levels for two or more different wavelengths included in an LED light. The controller 500 is configured produce outputs 521, 522 that individually adjust the two or more different wavelengths, according to the received user inputs 511, 512. The controller 500 may for example adjust variable resistors to increase or decrease the electrical power to LED elements of the two or more different wavelengths. The controller 500 may thus be configured to independently control LED elements corresponding to a plurality of different wavelengths that are included in an LED light. For example, the controller 500 may be configured to receive a user inputs 511 comprising an intensity level for the Be LEDs in FIG. 5A, and the controller 500 may be configured to receive a user inputs 512 comprising an intensity level for the Wi and We LEDs in FIG. 5A. The controller 500 may be configured to adjust the Be LEDs via output 521, and to adjust the Wi and We LEDs via output 522.

The controller 500 may include a timer 501. A user input 513 to the timer 501 may comprise intensity levels for two or more different wavelengths included in an LED light, similar to user inputs 511, 512, and may further comprise corresponding time-of day settings. The controller 500 may be configured to apply the settings received via user input 513 in one or more outputs 521, 522, at times of day as specified in the input 513.

It will be appreciated that a controller 500 and timer 501 may also included in any of the various lights disclosed herein, and that aquarium lights may likewise be configured according to any of the LED light embodiments disclosed herein.

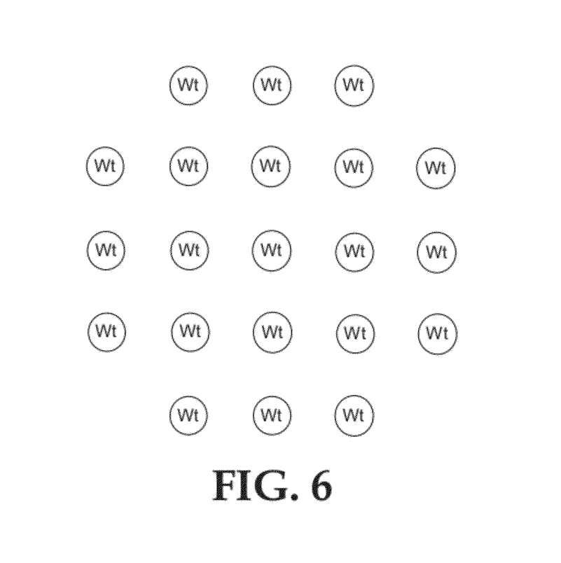

FIG. 6 illustrates an example light engine as may be included in a high-performance LED light configured for environmental lighting applications in accordance with some embodiments of this disclosure. An LED light incorporating one or more light engines such as illustrated in FIG. 6 is well suited for home and commercial lighting applications. In FIG. 6, all of the plurality of LED elements are 3000 Kelvin (K) Wt LED elements. Other embodiments may include substantially all Wt LED elements. In this context, “substantially all” refers to 75% or more.

Additional example embodiments according to FIG. 6 may include, for example, all or substantially all 6500 K We LED elements, or all or substantially all 12000 K Wi LED elements. Furthermore, all or substantially all of the illustrated LED elements may comprise stacked lenses configured to produce illumination angles equal to or greater than 90 degrees, for example, 90 degrees or 120 degrees. All or substantially all of the illustrated LED elements may comprise two 3 W LED chips 315 under the primary lens 300. A LED light according to FIG. 6 may incorporate the light engine module design and/or any of the various other features disclosed herein. In some embodiments, the LED

While various embodiments have been disclosed herein, other aspects and embodiments will be apparent to those skilled in art.

1. A high performance Light Emitting Diode (LED) grow light, comprising:
a plurality of LED elements arranged in at least one light engine group on a grow light surface, the light engine group comprising approximately:
9.5% LED elements with wavelengths in the 430-450 nm range;
9.5% LED elements with wavelengths in the 460-480 nm range;
19% LED elements with wavelengths in the 630-650 nm range;
48% LED elements with wavelengths in the 650-670 nm range;
9.5% LED elements with wavelengths in the 730-750 nm range; and
4.8% LED elements with wavelengths in the 500-550 nm range.

2. The high performance LED grow light of claim 1, wherein the light comprises two or more light engine groups, each light engine group comprising an identical number and distribution of LED elements having each of the different wavelengths.

3. The high performance LED grow light of claim 1, wherein the light comprises:
2 LED elements with wavelengths in the 430-450 nm range;
2 LED elements with wavelengths in the 460-480 nm range;
4 LED elements with wavelengths in the 630-650 nm range;
10 LED elements with wavelengths in the 650-670 nm range;
2 LED elements with wavelengths in the 730-750 nm range; and
1 LED elements with wavelengths in the 500-550 nm range.

4. The high performance LED grow light of claim 3, wherein the LED elements are arranged with an Rd, a Pk, and an Rd in a first row, an Rd, a Be, a FR, a Pe and an Rd in a second row, a Pk, an Rd, a Gr, an Rd, and a Pk in a third row, an Rd, a Pe, a FR, a Be and an Rd in a fourth row, and an Rd, a Pk, and an Rd in a fifth row.

5. The high performance LED grow light of claim 1, wherein the plurality of LED elements arranged in at least one light engine group are arranged in an octagonal pattern comprising 21 LEDs.

6. The high performance LED grow light of claim 1, wherein at least one of the plurality of LED elements comprises an acute angle lens defining a grow area illuminated by the LED element.

7. A Light Emitting Diode (LED) light, comprising:
a plurality of LED elements arranged in at least one light engine group on a lighting surface, each of the LED elements comprising an individual lens;
a multi-element lens comprising a plurality of additional lens elements, wherein each of the plurality of additional lens elements is stacked in a light path of one of the plurality of LED elements, so that light produced by an LED element first passes through an individual lens, and subsequently passes through an additional lens element of the multi-element lens, wherein the combined individual and additional lenses define an illumination angle for each LED element.

8. The LED light of claim 7, wherein the plurality of LED elements include LED elements of each of a plurality of different wavelengths.

9. The LED light of claim 8, wherein combined lenses for LED elements of a first wavelength define a first illumination angle, and combined lenses for LED elements of a second wavelength define a second illumination angle.

10. The LED light of claim 7, wherein substantially all of the plurality of LED elements are 3000 Kelvin (K) LED elements or 6500 K LED elements, and wherein substantially all of the illumination angles for the plurality of LED elements are equal to or greater than 90 degrees.

11. The LED light of claim 7, wherein the illumination angle produced by combined lenses for one or more of the plurality of LED elements is 90 degrees.

12. The LED light of claim 7, wherein the illumination angle produced by combined lenses for one or more of the plurality of LED elements is 60 degrees.

13. The LED light of claim 7, wherein the LED light is adapted for use in an aquarium by including LED elements with two or more different wavelengths selected from the group comprising: wavelengths in the 430-450 nm range; a combination of wavelengths producing a color temperature of substantially 6500 Kelvin (K); a combination of wavelengths producing a color temperature of substantially 12000 K; wavelengths in the 400-420 nm range; and wavelengths in the 460-480 nm range.

14. The LED light of claim 13, wherein the LED light comprises approximately:
19% LED elements with wavelengths in the 430-450 nm range;
24% LED elements with a combination of wavelengths producing a color temperature of substantially 6500 Kelvin (K);
9.5% LED elements with a combination of wavelengths producing a color temperature of substantially 12000 K;
9.5% LED elements with wavelengths in the 400-420 nm range; and
38% LED elements with wavelengths in the 460-480 nm range.

15. The LED light of claim 13, wherein the illumination angle produced by combined lenses for one or more of the plurality of LED elements is 60 degrees.

16. The LED light of claim 13, further comprising a controller configured to independently control LED elements corresponding to a plurality of the two or more different wavelengths.

17. The LED light of claim 16, wherein the controller includes a timer.

18. A Light Emitting Diode (LED) light, comprising:
a housing configured to house one or more removable light engine modules;
an LED power supply;
one or more removable light engine modules, each light engine module comprising:
an electrical interface configured to detachably couple with the LED power supply;
a Printed Circuit Board (PCB) and a plurality of LED elements disposed thereon, the plurality of LED elements defining a light engine group; and
a heat sink affixed to the PCB.

19. The LED light of claim 20, wherein each light engine module further comprises a multi-element lens covering the plurality of LED elements and including a lens element for each of the plurality of LED elements, wherein the multi-element lens is affixed to the light engine module and removable from the light engine module as a single unit along with the other elements of the light engine module.

20. The LED light of claim 20, wherein the LED light includes light engine modules of two different types, including a type 1 light engine module equipped with a second electrical interface, and a type 1 light engine module not equipped with a second electrical interface.

21. The LED light of claim 20, wherein the LED light includes two or more subsets of removable light engine modules, and wherein each subset of removable light engine modules is connected to a separate LED power supply and switch.
